(19) United States
(12) Patent Application Publication
(10) Pub. No.: US 2011/0109287 A1
(43) Pub. Date: May 12, 2011

(54) SEMICONDUCTOR PACKAGE AND DC-DC CONVERTER

(75) Inventors: Kazutoshi Nakamura, Kanagawa-ken (JP); Daisuke Minohara, Hyogo-ken (JP)

(73) Assignee: KABUSHIKI KAISHA TOSHIBA, Tokyo (JP)

(21) Appl. No.: 12/886,898

(22) Filed: Sep. 21, 2010

(30) Foreign Application Priority Data
Nov. 9, 2009 (JP) 2009-256263

(51) Int. Cl. G05F 1/10; H01L 23/495

(52) U.S. Cl. 323/282; 257/675; 257/E23.031

(57) ABSTRACT

According to one embodiment, a semiconductor package includes a chip, a plurality of bumps, a source frame, a drain frame, and a mold member. The chip has a lateral transistor formed inside the chip and has a top source electrode exposed on a first surface of the chip and a top drain electrode exposed on the first surface of the chip. The plurality of bumps are mounted on each of the top source electrode and the top drain electrode. The source frame is connected to the top source electrode through the bumps. The drain frame is connected to the top drain electrode through the bumps. The mold member embeds at least a part of each of the chip, the bumps, the source frame and the drain frame.

### CROSS-REFERENCE TO RELATED APPLICATIONS

This application is based upon and claims the benefit of priority from the prior Japanese Patent Application No. 2009-256263, filed on Nov. 9, 2009; the entire contents of which are incorporated herein by reference.

### FIELD

Embodiments described herein relate generally to a semiconductor package and a DC-DC converter.

### BACKGROUND

In recent years, with the reduction in drive voltage of a central processing unit (CPU) of a computer or the like, a synchronous rectification type power supply has been used in many cases as a power supply of the CPU. Examples of the synchronous rectification type power supply include a DC-DC converter. In the DC-DC converter, two power transistors are connected in series between a power supply potential and a ground potential, and an LC circuit is connected between an output terminal and a connection point of the two power transistors. The two power transistors are alternately put in a conductive state to output a high-frequency current from the connection point. Then, the high-frequency current is smoothed by the LC circuit to output a direct-current voltage from the output terminal. Further, a driver circuit controls a ratio of a time during which one of the two power transistors is in the conductive state to a time during which the other is in the conductive state. Thereby, the driver circuit controls a potential of the direct current.

Since a large current flows through the power transistors included in the DC-DC converter, vertical transistors, particularly vertical trench metal-oxide-semiconductor field-effect transistors (MOSFETs) have heretofore been used as the power transistors (for example, refer to JP-A 2002-368218 (Kokai)). In a chip having a vertical transistor formed therein, a source electrode and a drain electrode are provided on different surfaces of the chip, and thus a current flows in a vertical direction. Therefore an on-resistance per unit area of the chip can be reduced. In addition, the electrodes can be connected not by wire bonding but by bonding conductive plates and thus bonding resistance as well as interconnect resistance can be reduced.

However, the demands for improving response (di/dt) and suppression of ripple are increasing recently in a power supply for a CPU. So, it becomes important to achieve a higher speed (a higher switching frequency) of a power supply. To increase the speed of the power supply, a lateral MOSFET is more advantageous than a vertical trench MOSFET for the following reason. Specifically, in the vertical trench MOSFET, a gate electrode buried in a trench penetrates a base layer and enters a drain layer. Accordingly, a gate-drain capacitance that affects a switching speed is large and also is likely to vary. Further, it is difficult to perform silicidation of the entire gate electrode because the gate electrode is buried in the trench. Thus, the gate resistance tends to become high. For this reason, in the vertical trench MOSFET, Switching loss will become large if switching frequency is made high.

On the other hand, in the lateral MOSFET, a drain layer can be formed by a self-alignment process for performing impurity implantation using a gate electrode as a mask. Thus, a gate-drain capacitance can be sufficiently reduced and made uniform. Moreover, since the gate electrode is provided on a silicon substrate, silicidation of the entire gate electrode is easy to perform, and the gate resistance can be reduced. Accordingly, switching loss during a high-frequency switching operation can be reduced, which enables a high-speed operation. As a result, the response can be improved, and ripple can be suppressed.

However, in the lateral transistor, since both of a source electrode and a drain electrode are provided on one surface of a chip, plate-shaped conductive plates cannot be bonded as in the case of the vertical transistor. Therefore, mounting is performed by wire bonding. For this reason, the lateral transistor has a problem of high bonding resistance and interconnect resistance, which makes it unsuitable for applications such as a DC-DC converter that requires a large current to flow therethrough.

### BRIEF DESCRIPTION OF THE DRAWINGS

FIG. 1 is a plan view illustrating a semiconductor package according to a first embodiment;

FIG. 2 is a cross-sectional view taken along the A-A′ line in FIG. 1;

FIG. 3 is a plan view illustrating a chip, bumps and frames of the semiconductor package according to the first embodiment;

FIG. 4 is a plan view illustrating the chip and the bumps of the semiconductor package according to the first embodiment;

FIG. 5 is a cross-sectional view taken along the line B-B′ in FIG. 3;

FIG. 6 is a cross-sectional view taken along the line C-C′ in FIG. 4;

FIG. 7 is a cross-sectional view illustrating a semiconductor package according to a second embodiment;

FIG. 8 is a plan view illustrating a chip, bumps and frames of a semiconductor package according to a third embodiment;

FIG. 9 is a plan view illustrating the chip and the bumps of the semiconductor package according to the third embodiment;

FIG. 10 is a cross-sectional view taken along the line D-D′ in FIG. 9;

FIG. 11 is a circuit diagram illustrating a DC-DC converter according to a fourth embodiment;

FIG. 12 is a plan view illustrating a chip and bumps of a semiconductor package according to the fourth embodiment;

FIG. 13 is a plan view illustrating the chip, the bumps and frames of the semiconductor package according to the fourth embodiment;

FIG. 14 is a plan view illustrating the semiconductor package according to the fourth embodiment;

FIG. 15 is a cross-sectional view taken along the line E-E′ in FIG. 14;

FIG. 16 is a plan view illustrating a semiconductor package according to a fifth embodiment;

FIG. 17 is a cross-sectional view illustrating a semiconductor package according to a sixth embodiment; and

FIG. 18 is a plan view illustrating a chip, bumps and frames of a semiconductor package according to a seventh embodiment.

### DETAILED DESCRIPTION

In general, according to one embodiment, a semiconductor package includes a chip, a plurality of bumps, a source frame, a drain frame, and a mold member. The chip has a lateral transistor formed inside the chip and has a top source electrode exposed on a first surface of the chip and a top drain electrode exposed on the first surface of the chip. The plurality of bumps are mounted on each of the top source electrode and the top drain electrode. The source frame is connected to the top source electrode through the bumps. The drain frame is connected to the top drain electrode through the bumps. The mold member embeds at least a part of each of the chip, the bumps, the source frame and the drain frame.

According to another embodiment, a semiconductor package includes a first chip, a plurality of bumps, a second chip, a first frame, a second frame, a third frame, and a mold member. The first chip has a lateral transistor formed in the first chip and has a top source electrode exposed on a first surface of the first chip and a top drain electrode exposed on the first surface of the first chip. The plurality of bumps are mounted on each of the top source electrode and the top drain electrode. The second chip has a vertical transistor formed in the second chip, and has a source electrode and a drain electrode. One electrode out of the source electrode and the drain electrode is exposed on a first surface of the second chip. Another electrode out of the source electrode and the drain electrode is exposed on a second surface of the second chip. The first frame is connected to one top electrode out of the top source electrode and the top drain electrode through the bumps. The second frame is connected to another top electrode out of the top source electrode and the top drain electrode and to the one electrode through the bumps. The third frame is connected to the another electrode. The mold member embeds at least a part of each of the first chip, the bumps, the second chip, the first frame, the second frame and the third frame.

According to still another embodiment, a DC-DC converter includes a semiconductor package, an inductor and a capacitor. The semiconductor package includes a first chip, a plurality of bumps, a second chip, a first frame, a second frame, a third frame, and a mold member. The first chip has a lateral transistor formed in the first chip and has a top source electrode exposed on a first surface of the first chip and a top drain electrode exposed on the first surface of the first chip. The plurality of bumps are mounted on each of the top source electrode and the top drain electrode. The second chip has a vertical transistor formed in the first chip, and has a source electrode and a drain electrode. One electrode out of the source electrode and the drain electrode is exposed on a first surface of the second chip. Another electrode out of the source electrode and the drain electrode is exposed on a second surface of the second chip. The first frame is connected to one top electrode out of the top source electrode and the top drain electrode through the bumps. The second frame is connected to another top electrode out of the top source electrode and the top drain electrode and to the one electrode through the bumps. The third frame is connected to the another electrode. The mold member embeds at least a part of each of the first chip, the bumps, the second chip, the first frame, the second frame and the third frame. The inductor has one end connected to the second frame. The capacitor is connected between another end of the inductor and a reference potential. In addition, the high side power supply potential is applied to the first frame, and a low side power supply potential is applied to the third frame.

Embodiments of the invention will be described below with reference to the drawings.

First, a first embodiment is described.

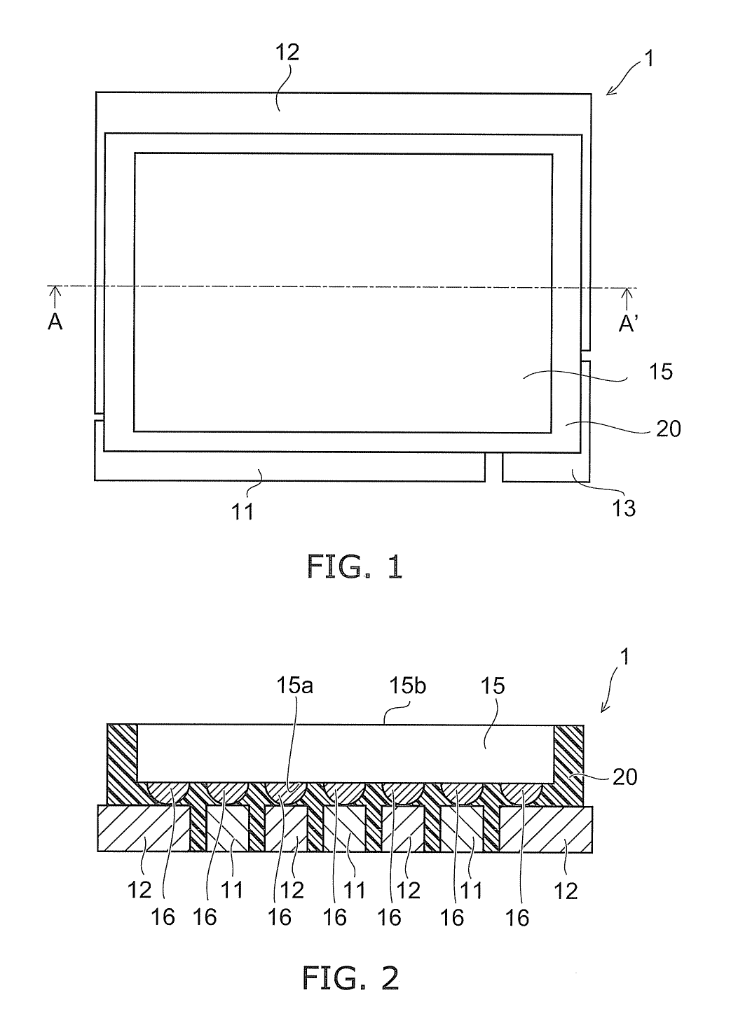

FIG. 1 is a plan view illustrating a semiconductor package according to this embodiment.

FIG. 2 is a cross-sectional view taken along the line A-A′ in FIG. 1.

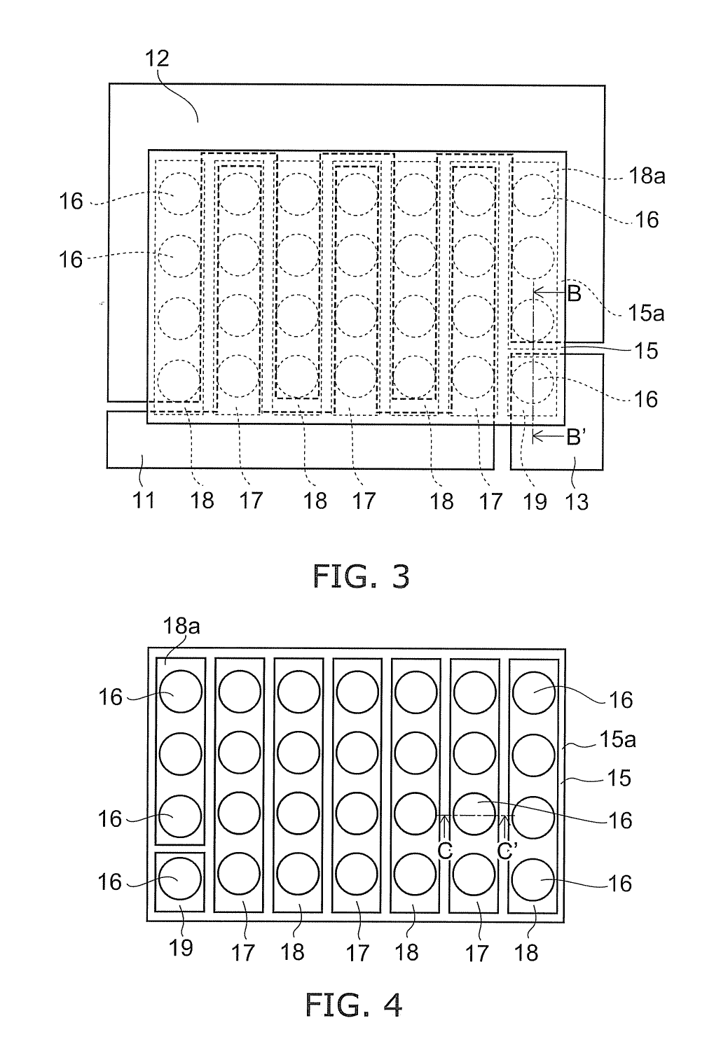

FIG. 3 is a plan view illustrating a chip, bumps and frames of the semiconductor package according to this embodiment.

FIG. 4 is a plan view illustrating the chip and the bumps of the semiconductor package according to this embodiment.

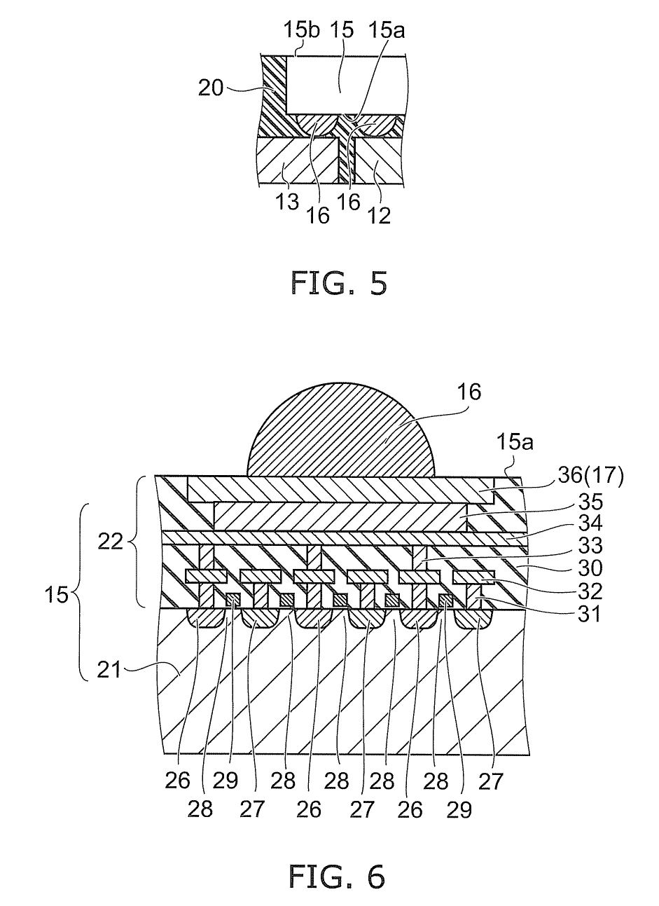

FIG. 5 is a cross-sectional view taken along the line B-B′ in FIG. 3.

FIG. 6 is a cross-sectional view taken along the line C-C′ in FIG. 4.

First, an overall configuration of a semiconductor package 1 according to this embodiment will be described.

As shown in FIGS. 1 and 2, a semiconductor package 1 is provided with a source frame 11, a drain frame 12 and a gate frame 13 in the form of plates. The source frame 11, the drain frame 12 and the gate frame 13 (which are also collectively called the “frames” in the first to third embodiments) are made of metal, e.g., copper, and arranged on the same plane in spaced relation to each other. Further, a chip 15 is provided on the frames. The chip 15 is mounted on the frames with bumps 16.

Further, a mold member 20 made of mold resin is provided a part of each of the frames, the entire bumps 16 and a part of the chip 15 are embedded in the mold member 20. Each frame is partially drawn out of the mold member 20. Note that, when seen from above, each frame need not stick out from the mold member 20. Moreover, each frame may have an extension part formed therein for connection to a connector of a motherboard or the like on which the semiconductor package 1 is mounted. A surface of each frame on a side not bonded to the bumps 16 is exposed on a lower surface of the mold member 20. Further, a back surface 15b of the chip 15 is exposed on an upper surface of the mold member 20.

Detailed configurations of the respective parts will be described below.

As shown in FIGS. 2 and 3, a lateral MOSFET is formed inside the chip 15, and top source electrodes 17, top drain electrodes 18 and a top gate electrode 19 (which are also collectively called the “top electrodes” in the first to third embodiments) are provided and exposed on a top surface 15a of the chip 15. The top electrodes are formed of metal such as copper or aluminum for example. The top surface 15a of the chip 15 faces the frames. The top source electrodes 17 and the top drain electrodes 18 have a stripe shape, are provided in plural number, respectively, and are arranged alternately and parallel to each other. The top gate electrode 19 has a rectangular shape and is disposed at a corner of the chip 15. For example, a top drain electrode 18a provided at the edge of the chip 15 is slightly shorter than the other top drain electrodes 18, which leaves an open space to dispose the top gate electrode 19. Note that no top electrode is provided on the back surface 15b of the chip 15.

As shown in FIGS. 3 to 5, the bumps 16 are mounted respectively on the top source electrodes 17, the top drain electrodes 18 and the top gate electrode 19 of the chip 15. The bumps 16 are, for example, solder balls. On each of the top source electrodes 17, multiple bumps 16 are arranged in a line along a longitudinal direction of the top source electrode 17. Similarly, on each of the top drain electrodes 18, multiple bumps 16 are arranged in a line along a longitudinal direction of the top drain electrode 18. Also, for example, one bump 16 is mounted on the top gate electrode 19.

The source frame 11 has a shape such that the source frame 11 is disposed in a region facing the top source electrodes 17 and not disposed in a region facing the top drain electrodes 18 and the top gate electrode 19. Likewise, the drain frame 12 has a shape such that the drain frame 12 is disposed in a region facing the top drain electrodes 18 and not disposed in a region facing the top source electrodes 17 and the top gate electrode 19. Further, the gate frame 13 has a shape such that the gate frame 13 is disposed in a region facing the top gate electrode 19 and not disposed in a region facing the top source electrodes 17 and the top drain electrodes 18.

To be more specific, the source frame 11 and the drain frame 12 each have a comb shape, and are disposed as if they mesh with each other. Comb-teeth portions of the source frame 11 face the top source electrodes 17 respectively, and comb-teeth portions of the drain frame 12 face the top drain electrodes 18 respectively. Further, a comb-teeth portion disposed at the edge of the drain frame 12 is shorter than the other comb-teeth portions, which leaves an open space to dispose the gate frame 13. The gate frame 13 has, for example, a rectangular shape and is disposed at a corner of the semiconductor package 1. Accordingly, the source frame 11 is connected only to the top source electrodes 17 through the bumps 16, the drain frame 12 is connected only to the top drain electrodes 18 through the bumps 16, and the gate frame 13 is connected only to the top gate electrode 19 through the bump 16.

As shown in FIG. 6, a silicon substrate 21 is provided in the chip 15, and a multilayer interconnect layer 22 is provided on the silicon substrate 21. In an upper layer portion of the silicon substrate 21, stripe-shaped source layers 26 and drain layers 27 are alternately formed, and spaces between the source layers 26 and the drain layers 27 serve as channel regions 28. Also, a gate oxide film (not shown) is formed on an upper surface of the silicon substrate 21, and gate electrodes 29 extending in the same direction as the source layers 26 and the drain layers 27 are provided directly above the channel regions 28 on the gate oxide film. The gate electrodes 29 are formed of suicide polysilicon. The lateral MOSFET is thus formed.

The multilayer interconnect layer 22 has multiple contacts 31, first interconnections 32, first vias 33, second interconnections 34, second vias 35 and third interconnections 36 embedded in an interlayer insulating film 30 sequentially from the lower layer side. The third interconnections 36 are exposed on the surface of the interlayer insulating film 30, and are the top electrodes described above. When seen from the top surface 15a side of the chip 15, the contacts 31 are arranged in a matrix and are each connected to the source layers 26 or the drain layers 27. The first interconnections 32 are each provided in a stripe pattern directly above the source layer 26 or the drain layers 27, and are each connected to the source layers 26 or the drain layers 27 through the contacts 31. The first vias 33 are arranged in a matrix and connected to the first interconnections 32. The second interconnections 34 are wider than the first interconnections 32, extend in a direction perpendicular to the first interconnections 32, and are each connected through the first vias 33 to the first interconnections connected to the source layers 26 or the first interconnections 32 connected to the drain layers 27. Similarly, the second vias 35 are arranged in a matrix and connected to the second interconnections 34. The third interconnections 36 are wider and thicker than the second interconnections 34, extend in a direction perpendicular to the second interconnections 34, and are each connected through the second vias 35 to the second interconnections 34 connected to the source layers 26 or the second interconnections 34 connected to the drain layers 27. The third interconnections 36 each have a thickness of, for example, about 3 micrometers.

In this way, the large number of fine source layers 26 and drain layers 27 are gathered to the relatively small number of third interconnections 36 and then drawn out. Among the third interconnections 36, those connected to the source layers 26 are the top source electrodes 17, and those connected to the drain layers 27 are the top drain electrodes 18. In other words, the top source electrodes 17 are connected to the multiple source layers 26 through the interconnections and the like in the multilayer interconnect layer 22, and the top drain electrodes 18 are connected to the multiple drain layers 27 through the interconnections and the like in the multilayer interconnect layer 22. Further, among the third interconnections 36, one connected to the gate electrodes 29 is the top gate electrode 19. Therefore, the top gate electrode 19 is connected to all the gate electrodes 29 through the interconnections and the like in the multilayer interconnect layer 22.

Next, effects of this embodiment will be described.

In the semiconductor package 1 according to this embodiment, the source frame 11 has a shape such that the source frame 11 is disposed in the region facing the top source electrodes 17 and not disposed in the region facing the top drain electrodes 18 and the top gate electrode 19. Accordingly, the source frame 11 is connected only to the top source electrodes 17 through the bumps 16. Likewise, the drain frame 12 has a shape such that the drain frame 12 is disposed in the region facing the top drain electrodes 18 and not disposed in the region facing the top source electrodes 17 and the top gate electrode 19. Accordingly, the drain frame 12 is connected only to the top drain electrodes 18 through the bumps 16. Further, the gate frame 13 has a shape such that the gate frame 13 is disposed in the region facing the top gate electrode 19 and not disposed in the region facing the top source electrodes 17 and the top drain electrodes 18. Accordingly, the gate frame 13 is connected only to the top gate electrode 19 through the bump 16.

Thus, each of the top electrodes of the chip 15 can be connected to the corresponding one of the plate-shaped frames and drawn out independently of each other. Further, the bumps 16 are mounted on approximately the entire surfaces of the third interconnections 36 as top interconnections, i.e., the top electrodes, in the multilayer interconnect layer 22, and are connected to the frames. Thus, a path of a current inputted to and outputted from the chip 15 can be reduced in length in a portion where the current flows through the top electrodes, and can also be increased in length in a portion where the current flows through the frames. Since a sheet resistance of the frames is much smaller than that of the top electrodes, a total interconnect resistance can be significantly reduced. Further, a bonding resistance can be reduced by mounting the bumps 16 on approximately the entire surfaces of the top electrodes.

In the semiconductor package 1 according to this embodiment, the absence of wire bonding allows the back surface 15b of the chip 15 to be exposed from the mold member 20. Accordingly, the back surface 15b of the chip 15 is exposed to the air without being covered with the mold member 20. As a result, a thermal resistance can be reduced, which enables efficient cooling of the chip 15. Further, by also exposing the surface of each frame on the side not bonded to the bumps 16 from the mold member 20, the thermal resistance can be further reduced. Generally, when the chip 15 is operated, a conduction loss inside the chip 15 raises the temperature of the chip 15. The increase in the temperature of the chip 15 increases the on-resistance. However, according to this embodiment, such an increase in on-resistance can be suppressed by efficiently cooling the chip 15. Here, reducing the thickness of the chip 15 can further improve heat radiation performance.

Next, a second embodiment will be described.

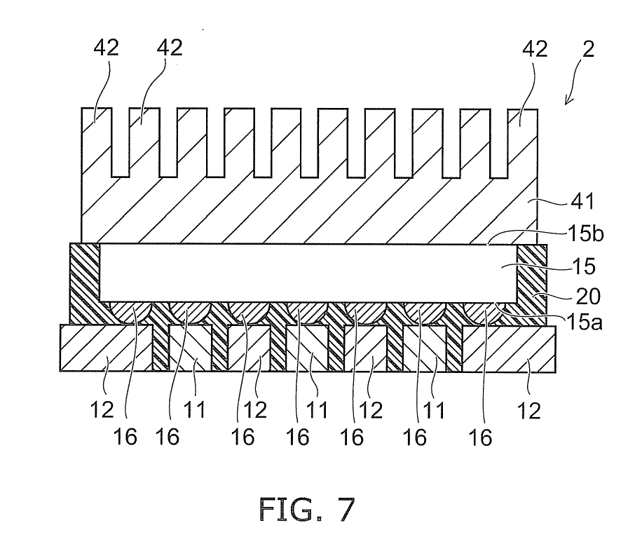

FIG. 7 is a cross-sectional view illustrating a semiconductor package according to this embodiment.

As shown in FIG. 7, in a semiconductor package 2 according to this embodiment, a heat sink 41 is further provided in addition to the configuration of the semiconductor package 1 (see FIG. 2) according to the first embodiment described above. The heat sink 41 is made of, for example, copper, is disposed outside the mold member 20, and is thermally connected to the chip 15 by being attached to the back surface 15b of the chip 15. For example, the heat sink 41 is in contact with the back surface 15b of the chip 15. Note that a highly thermally conductive bonding layer may be interposed between the heat sink 41 and the chip 15. On a surface of the heat sink 41 on a side not in contact with the chip 15, multiple radiation fins 42 are formed.

According to this embodiment, provision of the heat sink 41 can further facilitate heat radiation from the back surface 15b of the chip 15, which enables more effective cooling of the chip 15. Configurations and effects of this embodiment other than the above are the same as those in the first embodiment described above.

Next, a third embodiment will be described.

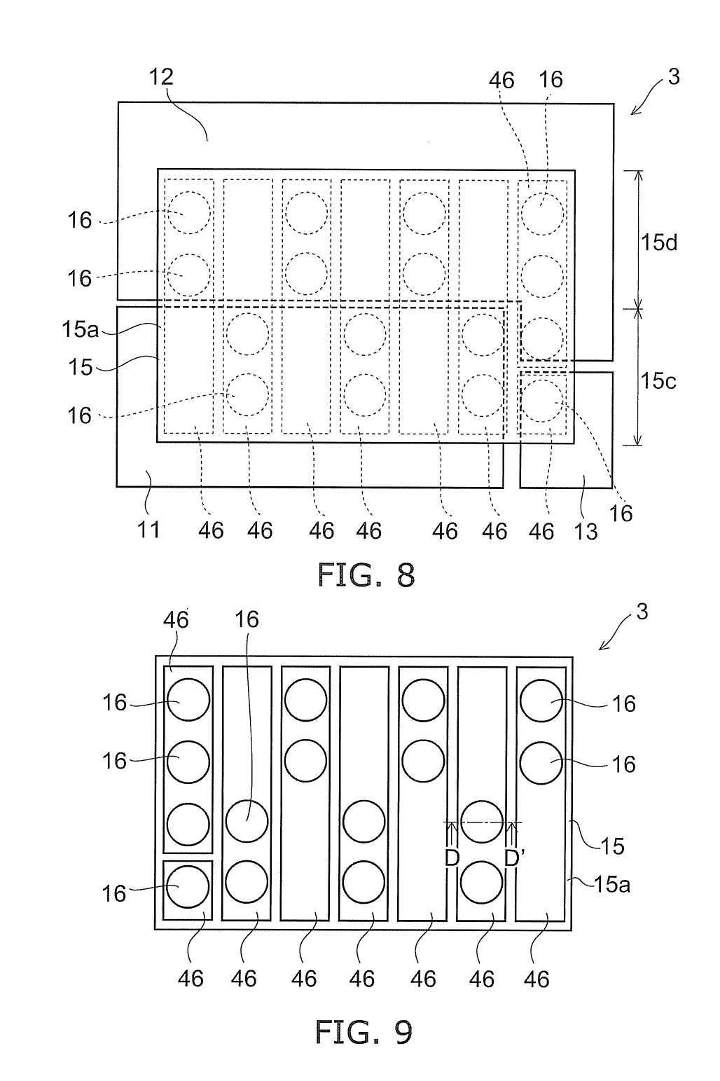

FIG. 8 is a plan view illustrating a chip, bumps and frames of a semiconductor package according to this embodiment.

FIG. 9 is a plan view illustrating the chip and the bumps of the semiconductor package according to this embodiment.

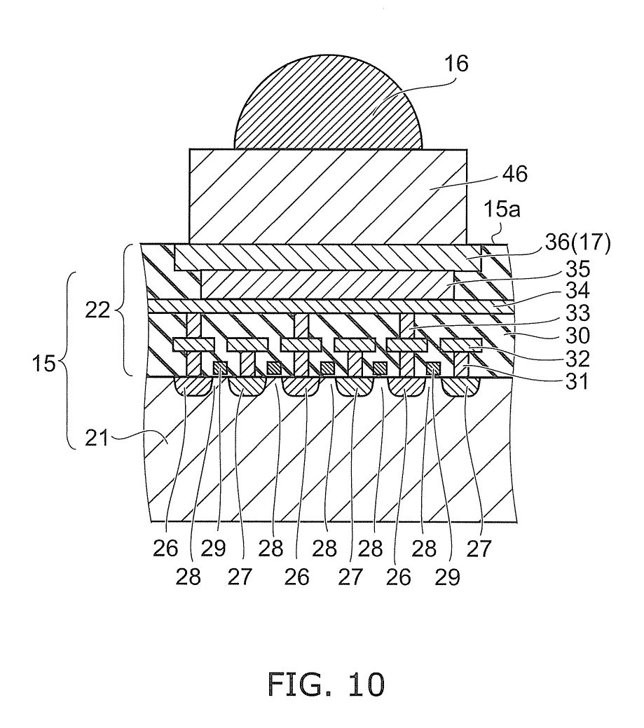

FIG. 10 is a cross-sectional view taken along the line D-D′ in FIG. 9.

As shown in FIGS. 8 to 10, a semiconductor package 3 according to this embodiment is different from the semiconductor package 1 (see FIG. 3) according to the first embodiment described above in that additional interconnections are provided on top electrodes, as well as in the arrangement of the bumps 16 and the shapes of the frames. Specifically, in the semiconductor package 3, the additional interconnections 46 are provided directly above the third interconnections 36 as the top electrodes. The additional interconnections 46 are made of, for example, copper, and are thicker than the top electrodes (third interconnections 36). Also, each of the additional interconnections 46 is provided on the corresponding one of the top electrodes in a manner approximately covering the entire surface of the top electrode, and is connected to the top electrode. Further, in the semiconductor package 3, among the bumps 16, those connected to top source electrodes 17 are disposed in a region 15c on one side of a top surface 15a of the chip 15, and those connected to top drain electrodes 18 are disposed in a region 15d on the other side of the top surface 15a of the chip 15. Accordingly, the bumps 16 connected to the top drain electrodes 18 are not disposed between the bumps 16 connected to the top source electrodes 17, and the bumps 16 connected to the top source electrodes 17 are not disposed between the bumps 16 connected to the top drain electrodes 18. Further, a source frame 11 has a rectangular shape, and a drain frame 12 has an L-shape.

According to this embodiment, the shapes of the source frame 11 and the drain frame 12 can be simplified by disposing the bumps 16 connected to the top source electrodes 17 and the bumps 16 connected to the top drain electrodes 18 separately in the region 15c and the region 15d, which are opposite to each other, on the top surface 15a of the chip 15. This facilitates processing of the frames as well as alignment when mounting the chip 15 on the frames. Moreover, a interconnect resistance in the frames can be further reduced. Further, an area increase in the frames further improves heat radiation performance. Meanwhile, provision of the additional interconnections 46 can compensate for an increase in resistance due to the reduced number of the bumps 16. Configurations and effects of this embodiment other than the above are the same as those in the first embodiment described above.

Next, a fourth embodiment will be described.

This embodiment is an embodiment of a DC-DC converter and a semiconductor package used therein.

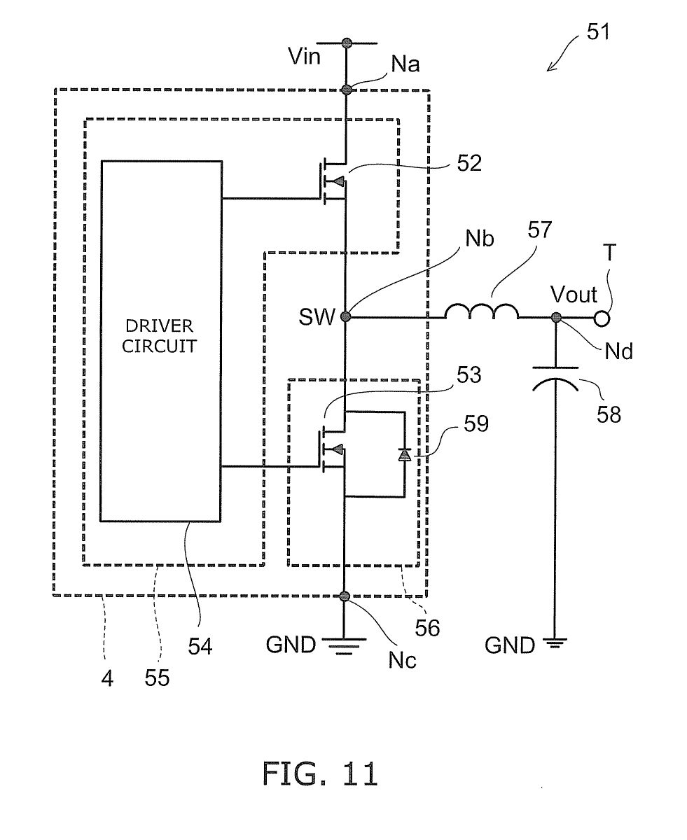

FIG. 11 is a circuit diagram illustrating a DC-DC converter according to this embodiment.

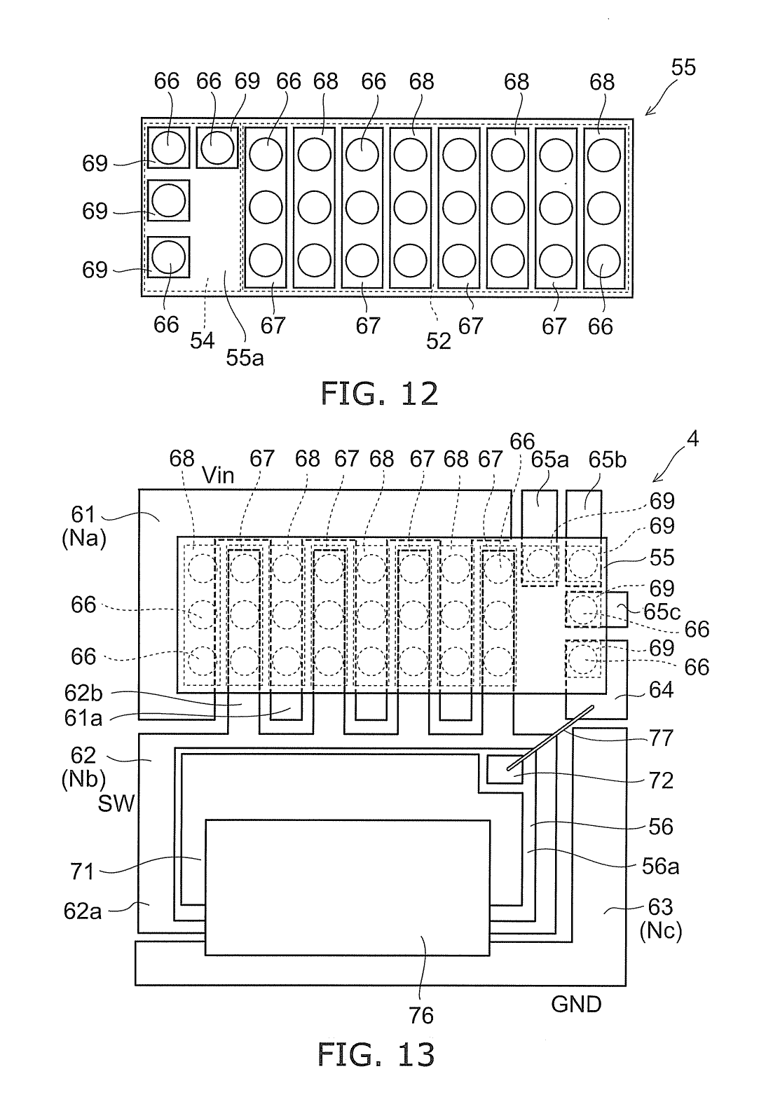

FIG. 12 is a plan view illustrating a chip and bumps of a semiconductor package according to this embodiment.

FIG. 13 is a plan view illustrating the chip, the bumps and frames of the semiconductor package according to this embodiment.

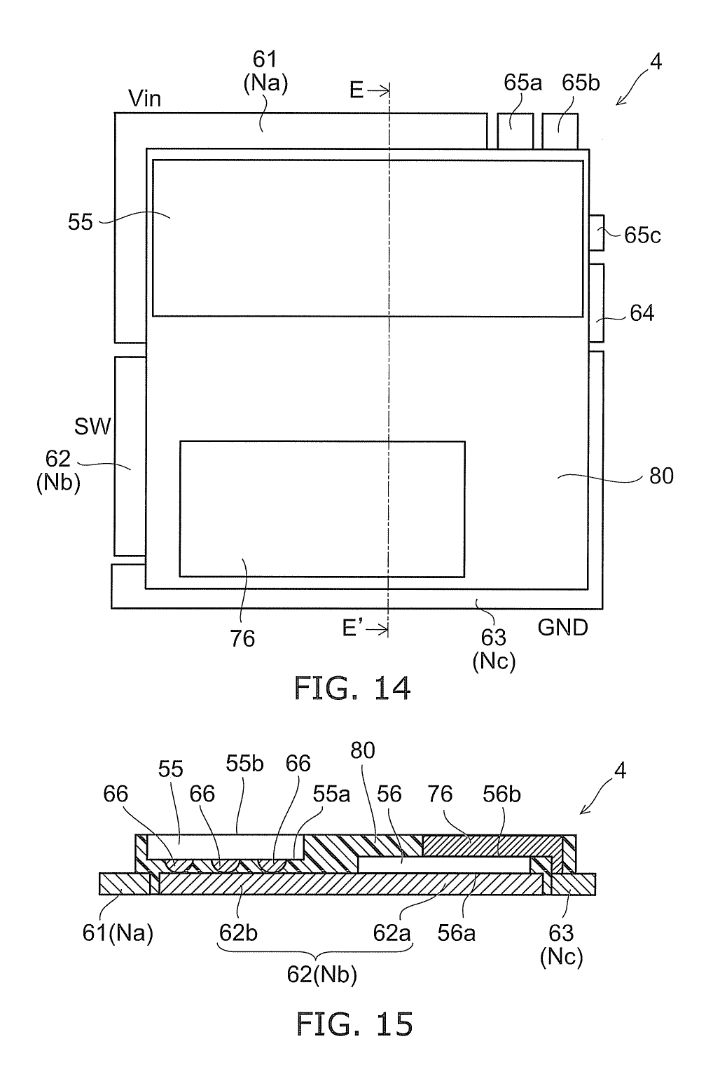

FIG. 14 is a plan view illustrating the semiconductor package according to this embodiment.

FIG. 15 is a cross-sectional view taken along the line E-E′ in FIG. 14.

First, an overall configuration of a DC-DC converter will be described.

As shown in FIG. 11, in a DC-DC converter 51 according to this embodiment, a high-side transistor 52 and a low-side transistor 53 are connected in series between an input potential Vin that is a high potential side power supply potential and a ground potential GND that is a low potential side power supply potential. The high-side transistor 52 is a lateral power MOSFET, and the low-side transistor 53 is a trench type vertical power MOSFET. The high-side transistor 52 and the low-side transistor 53 both have a conductivity type of, for example, N. Therefore, a drain of the high-side transistor 52 is connected to the input potential Vin at a node Na, a source of the high-side transistor 52 is connected to a drain of the low-side transistor 53 at a node Nb, and a source of the low-side transistor 53 is connected to the ground potential GND at a node Nc. Between the source and the drain of the low-side transistor 53, a diode 59 is connected, which causes a current to flow only in a direction from the source to the drain.

In the DC-DC converter 51, a driver circuit 54 is further provided, which supplies a gate potential to each of gates of the high-side transistor 52 and the low-side transistor 53. The high-side transistor 52 and the driver circuit 54 are formed on a single lateral chip 55. On the other hand, the low-side transistor 53 and the diode 59 are formed on a separate vertical chip 56. The chips 55 and 56 are mounted in a single semiconductor package 4.

Further, outside the semiconductor package 4 in the DC-DC converter 51, an inductor 57 and a capacitor 58 are provided to form an LC circuit. The inductor 57 is formed of, for example, a choke coil. The inductor 57 has one end connected to the node Nb and the other end connected to a node Nd. The capacitor 58 is connected between the node Nd and the ground potential GND. The node Nd is connected to an output terminal T of the DC-DC converter 51.

Next, a configuration of the chip 55 will be described.

As shown in FIG. 12, the high-side transistor 52 and the driver circuit 54 are formed in the chip 55. The chip 55 is approximately the same as the chip 15 in the first embodiment described above in the configuration of a portion where the high-side transistor 52 is formed. However, no top gate electrode is provided in the chip 55. The gate potential of the high-side transistor 52 is supplied directly from the driver circuit 54 formed in the same chip 55. On a top surface 55a of the chip 55, stripe-shaped top source electrodes 67 and top drain electrodes 68 are alternately disposed. In a portion of the chip 55 where the driver circuit 54 is formed, signal top electrodes 69 are provided on the top surface 55a. The top source electrodes 67, the top drain electrodes 68 and the signal top electrodes 69 (which are also collectively called the “top electrodes” in this embodiment) are made of, for example, copper. The configuration of the chip 55 other than the above is the same as that of the chip 15 in the first embodiment described above. Further, bumps 66 are mounted on the top electrodes. The bumps 66 are, for example, solder balls.

Next, a configuration of the chip 56 will be described.

As shown in FIG. 13, the chip 56 is a vertical chip having a source electrode 71 exposed on approximately the entire top surface 56a of the chip 56 and a gate electrode 72 exposed at a corner of the top surface 56a. Also, a drain electrode (not shown) is exposed on approximately the entire back surface 56b of the chip 56. The source electrode 71, the gate electrode 72 and the drain electrode (which are hereinafter collectively called the “electrodes”) are made of metal, e.g., copper.

Next, a mode of mounting the chips 55 and 56 will be described.

As shown in FIGS. 13 to 15, in the semiconductor package 4, a high potential side frame 61 (first frame), an output side frame 62 (second frame), a low potential side frame 63 (third frame), a gate frame 64 and driver circuit frames 65a, 65b and 65c (which are also collectively called the “frames” in this embodiment) are provided in the form of plates. The frames are made of metal, e.g., copper, and arranged on the same plane in spaced relation to each other.

The chip 55 is provided on the high potential side frame 61, the output side frame 62, the gate frame 64 and the driver circuit frames 65a, 65b and 65c. The top surface 55a of the chip 55 faces these frames. As with the first embodiment described above, the high potential side frame 61 has a shape such that the high potential side frame 61 is disposed in a region facing the top drain electrodes 68 of the chip 55 and not disposed in a region facing the top source electrodes 67 and the signal top electrodes 69. Moreover, a portion of the output side frame 62 facing the chip 55 has a shape such that the portion is disposed in a region facing the top source electrodes 67 and not disposed in a region facing the top drain electrodes 68 and the signal top electrodes 69. Further, the gate frame 64 and the driver circuit frames 65a, 65b and 65c each have a shape such that the driver circuit frames 65a, 65b and 65c are each disposed in a region facing the signal top electrodes 69 and not disposed in a region facing the top source electrodes 67 and the top drain electrodes 68.

To be more specific, the high potential side frame 61 has a comb shape, and comb-teeth portions 61a thereof face the top drain electrodes 68, respectively. In the output side frame 62, a rectangular portion 62a and multiple comb-teeth portions 62b extending in one direction from the rectangular portion 62a are provided. The comb-teeth portions 62b face the top source electrodes 67, respectively. The comb-teeth portions 61a and the comb-teeth portions 62b are alternately disposed as if they mesh with each other. Accordingly, the high potential side frame 61 is connected to the top drain electrodes 68 through the bumps 66, the comb-teeth portions 62b of the output side frame 62 are connected to the top source electrodes 67 through the bumps 66, and the gate frame 64 and the driver circuit frames 65a, 65b and 65c are connected to the signal top electrodes 69 through the bumps 66, respectively.

Meanwhile, the chip 56 is provided on the rectangular portion 62a of the output side frame 62. The back surface 56b of the chip 56 faces the output side frame 62, and a drain electrode (not shown) formed on the back surface 56b is connected to the rectangular portion 62a through a solder layer (not shown) and the like. The low potential side frame 63 has an L-shape and is disposed so as to face two sides of the rectangular portion 62a of the output side frame 62. Moreover, a conductive plate 76 made of, for example, copper is provided on the source electrode 71 provided on the top surface 56a of the chip 56, and is connected to the source electrode 71. The conductive plate 76 extends in a direction from directly above the chip 56 toward the low potential side frame 63, is bent to wrap around the side of the chip 56, and is thus connected to the low potential side frame 63.

Thus, a current path is formed, in which the high potential side frame 61, the top drain electrodes 68 of the chip 55, the top source electrodes 67 of the chip 55, the output side frame 62, the drain electrode of the chip 56, the source electrode 71 of the chip 56, the conductive plate 76 and the low potential side frame 63 are arranged in this order. When this is put into the circuit diagram shown in FIG. 11, the high potential side frame 61 corresponds to the node Na, the output side frame 62 corresponds to the node Nb, and the low potential side frame 63 corresponds to the node Nc. One of the signal top electrodes 69 of the chip 55 is connected to the gate frame 64 through the bump 66, and the gate frame 64 is connected to the gate electrode 72 of the chip 56 through a wire 77.

As shown in FIGS. 14 and 15, in the semiconductor package 4, a mold member 80 made of mold resin is provided so that the frames, the chips 55 and 56, the bumps 66 and the conductive plate 76 are embedded in the mold member 80. Moreover, a portion of each of the frames is drawn out of the mold member 80 as a connection terminal. Here, lower surfaces of the respective frames, i.e., the high potential side frame 61, the output side frame 62, the gate frame 64 and the driver circuit frames 65a, 65b and 65c, on a side not bonded to the bumps 66, and a surface of the low potential side frame 63 on a side not connected to the conductive plate 76 are exposed on a lower surface of the mold member 80. Further, the back surface 55b of the chip 55 and a surface of the conductive plate 76 on a side not connected to the chip 56 are exposed on an upper surface of the mold member 80.

In the DC-DC converter 51 according to this embodiment, in a state where the input potential Vin is applied to the high potential side frame 61 (node Na) and the ground potential GND is applied to the low potential side frame 63 (node Nc), the driver circuit 54 alternately puts the high-side transistor 52 and the low-side transistor 53 in a conductive state. Accordingly, a high-frequency current SW whose potential level takes two values, the input potential Vin and the ground potential GND, is outputted from the output side frame 62 (node Nb). This high-frequency current SW is smoothed by the LC circuit including the inductor 57 and the capacitor 58, and then outputted from the output terminal T as a direct current having a constant output potential Vout. In this event, the driver circuit 54 controls a ratio of a conduction time of the high-side transistor 52 to a conduction time of the low-side transistor 53, thereby controlling the output potential Vout.

Next, effects of this embodiment will be described.

In the DC-DC converter 51 according to this embodiment, the lateral power MOSFET is used as the high-side transistor 52. Accordingly, particularly in the high-side transistor of the DC-DC converter, which is required to operate at faster speed, a gate-drain capacitance can be reduced and made uniform, and also a gate resistance can be reduced. As a result, response of the high-side transistor 52 is improved, and ripple is suppressed. Thus, a high-speed operation of the DC-DC converter 51 is made possible.

When a lateral MOSFET is mounted on a DC-DC converter, there has heretofore been a problem that mounting of a chip by wire bonding increases a bonding resistance and a interconnect resistance. However, according to this embodiment, when the chip 55 is mounted on the frames as in the configuration described above, the source layers and the drain layers of the lateral MOSFET can be drawn out by the plate-shaped frames, as in the case of the first embodiment described above. Thus, a bonding resistance and a interconnect resistance can be reduced. Accordingly, the influence of parasitic inductance can be suppressed, and switching loss can be reduced. As a result, a large current can be conducted to the high-side transistor 52 at a high frequency.

On the other hand, the vertical trench MOSFET having a lower on-resistance is used as the low-side transistor 53 since preference is given to reduction in conduction loss over speeding up. As described above, in this embodiment, optimum devices can be combined to fit the characteristics required for the high-side transistor and the low-side transistor.

Moreover, in the DC-DC converter 51 according to this embodiment, the high-side transistor 52, the low-side transistor and the driver circuit 54 are provided in the single semiconductor package 4. Accordingly, when the driver circuit 54 supplies the gate potential to the high-side transistor 52 and the low-side transistor 53, the influence of parasitic inductance can be suppressed, and the switching loss can be reduced. Particularly, the high-side transistor 52 which is strongly required to operate at faster speed is formed in the same chip 55 as the driver circuit 54, and thus the influence of parasitic inductance on the supply of the gate potential can be suppressed more effectively.

Further, in the semiconductor package 4 according to this embodiment, the absence of wire bonding allows the lower surfaces of the frames, the back surface 55b of the chip 55 and one side of the conductive plate 76 to be exposed on the surface of the mold member 80. Thus, heat radiation performance can be improved. Note that, as shown in FIG. 15, although the vertical chip 56 is thinner than the lateral chip 55, a total thickness of the chip 55 and the bump 66 is equal to a total thickness of the chip 56 and the conductive plate 76. In the chip 56 having the vertical trench MOSFET formed therein, since a current flows in a thickness direction of the chip, the on-resistance can be reduced by reducing the thickness of the chip. On the other hand, in the chip 55 having the lateral MOSFET formed therein, since a current flows on the surface of the chip, the thickness of the chip does not affect the on-resistance. Therefore, it is easy to adjust the thickness of the lateral chip 55 without affecting electrical characteristics of the chip 55, and to make the total thickness of the chip 55 and the bump 66 equal to the total thickness of the chip 56 and the conductive plate 76.

Next, a fifth embodiment will be described.

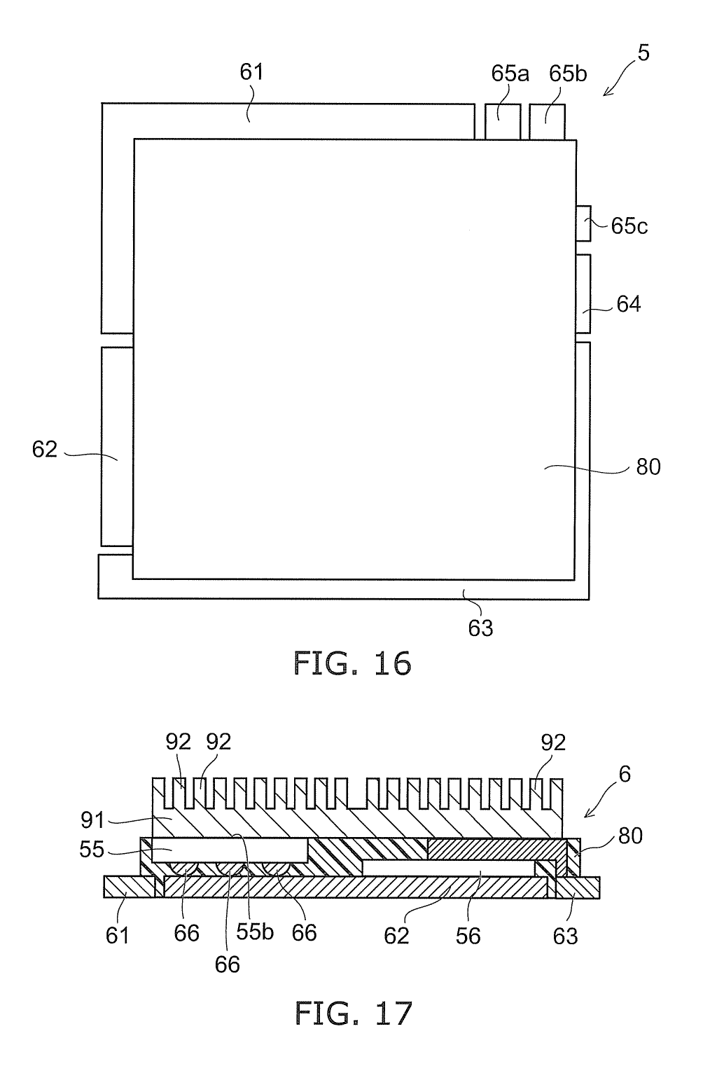

FIG. 16 is a plan view illustrating a semiconductor package according to this embodiment.

As shown in FIG. 16, in a semiconductor package 5 according to this embodiment, the chip 55 and the conductive plate 76 are covered with the mold member 80. Accordingly, compared with the fourth embodiment described above, the chip 55 and the conductive plate 76 can be reliably protected by the mold member 80, while heat radiation performance decreases. Configurations and effects of this embodiment other than the above are the same as those in the fourth embodiment described above.

Next, a sixth embodiment will be described.

FIG. 17 is a cross-sectional view illustrating a semiconductor package according to this embodiment.

As shown in FIG. 17, this embodiment is an example of combining the second and fourth embodiments described above. In other words, in a semiconductor package 6 according to this embodiment, a heat sink 91 is further provided in addition to the configuration of the semiconductor package 4 (see FIG. 15, etc.) according to the fourth embodiment described above.

The heat sink 91 is made of, for example, copper, and is disposed outside the mold member 80, and is thermally connected to the chip 55 and the conductive plate 76 by being attached to the back surface 55b of the chip 55 and the back surface of the conductive plate 76 directly or with a highly thermally conductive bonding layer or the like interposed therebetween. Since the back surfaces have a low potential, there is no problem even if the back surface 55b of the chip 55 and the back surface of the conductive plate 76 are electrically connected to each other. On a surface of the heat sink 91 on a side not in contact with the chip 55 and the conductive plate 76, multiple radiation fins 92 are formed. According to this embodiment, provision of the heat sink 91 can further facilitate heat radiation from the chips 55 and 56. Configurations and effects of this embodiment other than the above are the same as those in the fourth embodiment described above.

Next, a seventh embodiment will be described.

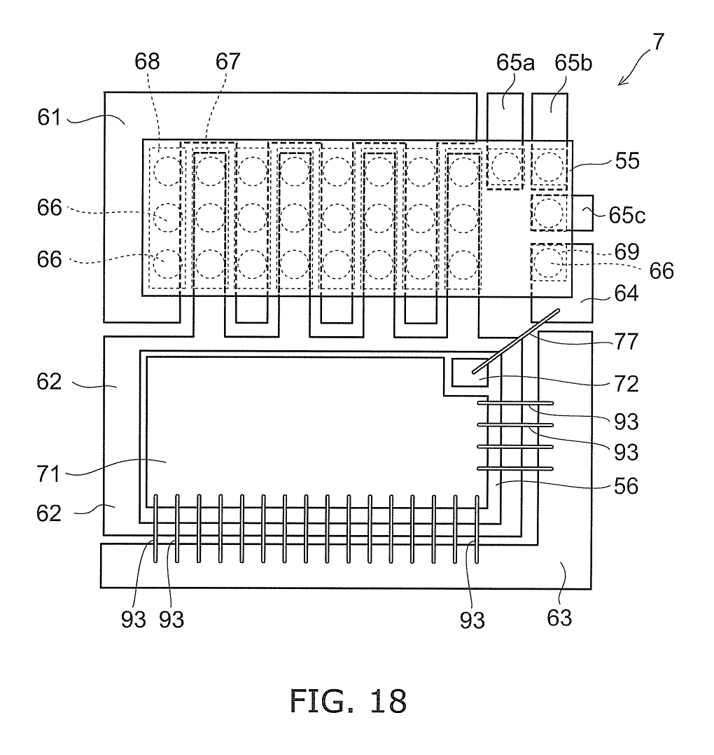

FIG. 18 is a plan view illustrating a chip, bumps and frames of a semiconductor package according to this embodiment.

As shown in FIG. 18, in a semiconductor package 7 according to this embodiment, multiple interconnections 93 are provided in place of the conductive plate 76 when compared with the semiconductor package 4 (see FIG. 13) according to the fourth embodiment described above. Each of the interconnections 93 has one end connected to the source electrode 71 and the other end connected to the low potential side frame 63. Thus, the source electrode 71 of a chip 56 is connected to the low potential side frame 63 through the interconnections 93. Moreover, the interconnections 93 are covered with the mold member 80 (see FIG. 13).

Accordingly, a process of connecting the source electrode 71 of the chip 56 to the low potential side frame 63 through the interconnections 93 can be combined with a process of connecting the gate electrode 72 to the signal top electrode 69 of the driver circuit 54 through the wire 77. Thus, a manufacturing process can be simplified. Configurations and effects of this embodiment other than the above are the same as those in the fourth embodiment described above. Note that a back surface 55b of the chip 55 may be either exposed from the mold member 80 or covered with the mold member 80.

While the invention has been described above with reference to the embodiments, the invention is not limited to those embodiments. The embodiments described above can be implemented in combination thereof. For example, in the DC-DC converter 51 according to the fourth embodiment, the semiconductor package 4 may be replaced by any of the semiconductor packages 5 to 7 according to the fifth to seventh embodiments. Moreover, any of the semiconductor packages 1 to 3 according to the first to third embodiments may be used as a high-side transistor to form a DC-DC converter. Further, the respective semiconductor packages according to the embodiments described above may be used in applications other than the DC-DC converter. Furthermore, those skilled in the art can suitably make design change as well as addition or deletion of components on any of the above embodiments without departing from the gist of the invention, and such variations are also encompassed within the scope of the invention. For example, the range of the mold member covering the chip, the bumps, the frames and the like can be arbitrarily designed in consideration of durability, heat radiation performance and the like of the semiconductor package. It is only required that at least a part of each of the above chips, bumps and frames is embedded in the mold member.

1. A semiconductor package comprising:
a chip having a lateral transistor formed inside the chip and having a top source electrode exposed on a first surface of the chip and a top drain electrode exposed on the first surface of the chip;
a plurality of bumps mounted on each of the top source electrode and the top drain electrode;
a source frame connected to the top source electrode through the bumps;
a drain frame connected to the top drain electrode through the bumps; and
a mold member embedding at least a part of each of the chip, the bumps, the source frame and the drain frame.

2. The package according to claim 1, wherein
the source frame is disposed in a region facing the top source electrode and not disposed in a region facing the top drain electrode, and
the drain frame is disposed in a region facing the top drain electrode and not disposed in a region facing the top source electrode.

3. The package according to claim 2, wherein
each of the top source electrode and the top drain electrode has a stripe shape,
the top source electrode and the top drain electrode are alternately arranged on the surface of the chip,
each of the source frame and the drain frame has a comb shape,
a comb-teeth portion of the source frame faces the top source electrode, and
a comb-teeth portion of the drain frame faces the top drain electrode.

4. The package according to claim 1, wherein
the bumps connected to the top drain electrode are not disposed between the bumps connected to the top source electrode, and
the bumps connected to the top source electrode are not disposed between the bumps connected to the top drain electrode.

5. The package according to claim 1, wherein a surface of the source frame on a side not bonded to the bumps is exposed from the mold member and a surface of the drain frame on a side not bonded to the bumps is exposed from the mold member.

6. The package according to claim 1, wherein a second surface of the chip is exposed from the mold member.

7. The package according to claim 6, further comprising a heat sink attached to the second surface of the chip.

8. A semiconductor package comprising:
a first chip having a lateral transistor formed in the first chip and having a top source electrode exposed on a first surface of the first chip and a top drain electrode exposed on the first surface of the first chip;
a plurality of bumps mounted on each of the top source electrode and the top drain electrode;
a second chip having a vertical transistor formed in the second chip, having a source electrode and a drain electrode, one electrode out of the source electrode and the drain electrode being exposed on a first surface of the second chip, and another electrode out of the source electrode and the drain electrode being exposed on a second surface of the second chip;
a first frame connected to one top electrode out of the top source electrode and the top drain electrode through the bumps;
a second frame connected to another top electrode out of the top source electrode and the top drain electrode and to the one electrode through the bumps;
a third frame connected to the another electrode; and
a mold member embedding at least a part of each of the first chip, the bumps, the second chip, the first frame, the second frame and the third frame.

9. The package according to claim 8, wherein a driver circuit for supplying a gate potential of the lateral transistor and a gate potential of the vertical transistor is formed in the first chip.

10. The package according to claim 8, wherein
the first frame is disposed in a region facing the one top electrode and not disposed in a region facing the another top electrode, and
the second frame is disposed in a region facing the another top electrode and not disposed in a region facing the one top electrode.

11. The package according to claim 10, wherein
each of the top source electrode and the top drain electrode has a stripe shape,
the top source electrodes and the top drain electrodes are alternately arranged on the first surface of the first chip,
the first frame has a comb shape,
a portion of the second frame facing the first chip has a comb shape,
a comb-teeth portion of the first frame faces the one top electrode, and
a comb-teeth portion of the second frame faces the other top electrode.

12. The package according to claim 8, wherein a surface of the first frame on a side not bonded to the bumps is exposed from the mold member, a surface of the second frame on a side not bonded to the bumps is exposed from the mold member, and a surface of the third frame on a side not connected to the another electrode is exposed from the mold member.

13. The package according to claim 8, further comprising:
a conductive plate connected between the another electrode and the third frame,
a second surface of the first chip and a surface of the conductive plate on a side not connected to the second chip are exposed from the mold member.

14. The package according to claim 13, further comprising a heat sink connected to the second surface of the first chip and the surface of the conductive plate on a side not connected to the second chip.

15. A DC-DC converter comprising:
a semiconductor package including:
a first chip having a lateral transistor formed in the first chip and having a top source electrode exposed on a first surface of the first chip and a top drain electrode exposed on the first surface of the first chip;
a plurality of bumps mounted on each of the top source electrode and the top drain electrode;
a second chip having a vertical transistor formed in the first chip, having a source electrode and a drain electrode, one electrode out of the source electrode and the drain electrode being exposed on a first surface of the second chip, and another electrode out of the source electrode and the drain electrode being exposed on a second surface of the second chip;
a first frame connected to one top electrode out of the top source electrode and the top drain electrode through the bumps;
a second frame connected to another top electrode out of the top source electrode and the top drain electrode and to the one electrode through the bumps;
a third frame connected to the another electrode, and
a mold member embedding at least a part of each of the first chip, the bumps, the second chip, the first frame, the second frame and the third frame;
an inductor having one end connected to the second frame; and
a capacitor connected between another end of the inductor and a reference potential,
a high side power supply potential being applied to the first frame, and a low side power supply potential being applied to the third frame.

16. The converter according to claim 15, wherein a driver circuit for supplying a gate potential of the lateral transistor and a gate potential of the vertical transistor is formed in the first chip.

17. The converter according to claim 15, wherein
the first frame is disposed in a region facing the one top electrode and not disposed in a region facing the another top electrode, and
the second frame is disposed in a region facing the another top electrode and not disposed in a region facing the one top electrode.

18. The converter according to claim 17, wherein
each of the top source electrode and the top drain electrode has a stripe shape,
the top source electrodes and the top drain electrodes are alternately arranged on the first surface of the first chip,
the first frame has a comb shape,
a portion of the second frame facing the first chip has a comb shape,
a comb-teeth portion of the first frame faces the one top electrode, and
a comb-teeth portion of the second frame faces the another top electrode.

19. The converter according to claim 15, wherein a surface of the first frame on a side not bonded to the bumps is exposed from the mold member, a surface of the second frame on a side not bonded to the bumps is exposed from the mold member, and a surface of the third frame on a side not connected to the another electrode is exposed from the mold member.

20. The converter according to claim 15, further comprising:
a conductive plate connected between the another electrode and the third frame,
a second surface of the first chip and a surface of the conductive plate on a side not connected to the second chip are exposed from the mold member.
